(19) United States
(12) Patent Application Publication
(10) Pub. No.: US 2010/0254081 A1
(43) Pub. Date: Oct. 7, 2010

(54) Heat exchange system with a heat exchanger and a method for the manufacture of a heat exchange system

(75) Inventors: Holger Koenig, Kressbronn (DE); Franz Summerer, Kottgeisering (DE); Stanislav Perencevic, Muenchen (DE)

Correspondence Address: TOWNSEND AND TOWNSEND AND CREW, LLP, TWO EMBARCADERO CENTER, EIGHTH FLOOR, SAN FRANCISCO, CA, 94111-3834, US

(73) Assignee: A-HEAT ALLIED HEAT EXCHANGE TECHNOLOGY AG, Muenchen (DE)

(21) Appl. No.: 12/667,932

(22) PCT Filed: May 23, 2008
(86) PCT No.: PCT/EP08/56366

§ 371 Date: Jun. 3, 2010

(30) Foreign Application Priority Data
Jul. 9, 2007 (EP) 07112060.4

(51) Int. Cl. G06F 1/20; H05K 7/20; F28F 13/00; F28F 19/02; B21D 53/02; F28D 5/00

(52) U.S. Cl. 361/679.46; 361/701; 165/133; 165/134.1; 29/890.03; 62/314

(57) ABSTRACT

The invention relates to a heat exchange system (1) having a heat exchanger (2) for the exchange of heat between a fluid (3) and an environmental atmosphere. The heat exchanger (2) in this respect includes an inlet passage (4), an outlet passage (5) and a heat transfer device (6) having a plurality of micro-passages (61), with the inlet passage (4) being in flow communication with an inlet segment (62) of the heat transfer device (6) and the outlet passage (5) being in flow communication with an outlet segment (63) of the heat transfer device (6) such that the fluid (3) for the exchange of heat with the environmental atmosphere can be supplied from the inlet passage (4) via the inlet segment (62), through the plurality of micro-passages (61) of the heat transfer device (6), and via the outlet segment (63) to the outlet passage (5). In accordance with the invention, the heat exchange system (1) includes a compensation means (7) for the compensation of thermomechanical strains. The invention furthermore relates to a method for the manufacture of a heat exchange system (1) in accordance with the invention.

The invention relates to a heat exchange system with a heat exchanger and to a method for the manufacture of a heat exchange system in accordance with the preamble of the independent claim of the respective category.

The use of heat exchange systems is known in a number applications from the prior art which can practically not be overseen. Heat exchangers are used in refrigeration systems such as in common domestic refrigerators, in air-conditioning systems for buildings or in vehicles of all kinds, in particular in motor vehicles, aircraft and ships, as water coolers or as oil coolers in combustion engines, as condensers in refrigerant circuits and in further innumerable different applications which are all well-known to the person of ordinary skill in the art.

In this respect, there are different possibilities of sensibly classifying the heat exchangers from very different applications. One attempt is to carry out a distinguishing by the structure or by the manufacture of the different types of heat exchangers.

A division can thus be made in accordance with so-called “finned heat exchangers”, on the one hand, and “mini-passage” or “micro-passage” heat exchangers, on the other hand.

The finned heat exchangers which have been well-known for a very long time serve, like all types of heat exchangers, for the transfer of heat between two media, e.g., but not only, for the transfer from a cooling medium to air or vice versa, such as is known, for example, from a classical domestic refrigerator in which heat is emitted to environmental air via the heat exchanger for the production of a cooling capacity in the interior of the refrigerator.

The environmental medium outside the heat exchanger, that is e.g. water, oil or frequently simply the environmental air which takes up the heat, for example, or from which heat is transferred to the heat exchanger, is either cooled or heated accordingly in this process. The second medium can e.g. be a liquid cold carrier or heat carrier or an evaporating or condensing refrigerant. In any case, the environmental medium, that is e.g. the air, has a substantially lower heat transfer coefficient than the second medium, that is e.g. the refrigerant, which circulates in the heat exchanger system. This is balanced by highly different heat transfer surfaces for the two media. The medium with the high heat transfer coefficient flows in the pipe which has a very enlarged surface at which the heat transfer e.g. to the air takes place by thin metal sheets (ribs, fins) at the outer side.

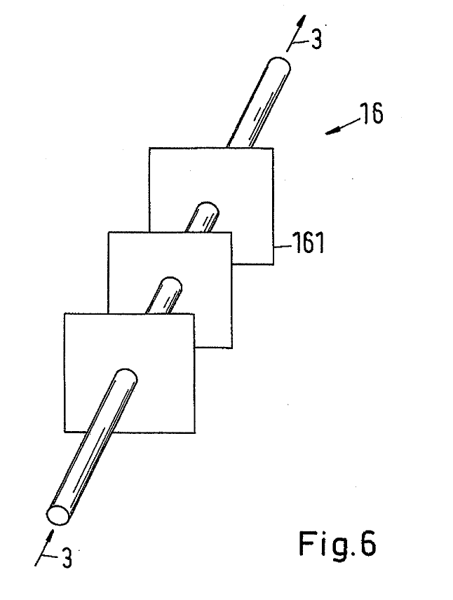

FIG. 6 shows a simple example of a finned heat exchanger which is known per se.

The ratio of the outer surface to the inner surface depends in this respect on the fin geometry (=pipe diameter, pipe arrangement and pipe spacing) as well as on the fin spacing. The fin spacing is selected differently for different applications. However, it should be as small as possible from a purely thermodynamic aspect, but not so small that the pressure loss at the air side is too large. An efficient optimum is at approximately 2 mm, which is a typical value for condensers and dry coolers.

The manufacture of these so-called finned heat exchangers takes place in accordance with a standardized process known for a long time. The fins are stamped using a press and a special tool and are placed in packets with one another. Subsequently, the pipes are pushed in and expanded either mechanically or hydraulically so that a very good contact, and thus a good heat transfer, arises between the pipe and the fins. The individual pipes are then connected to one another, often soldered or brazed to one another, by bends and inlet tanks and outlet tanks.

The efficiency is in this respect substantively determined by the fact that the heat which is transferred between the fin surface and the air has to be transferred to the pipe via heat conduction through the fins. This heat transfer is the more effective, the higher the conductivity or the thickness of the fin is, but also the smaller the spacing between the pipes is. One speaks of fin efficiency here. Aluminum is therefore primarily used as the fin material today which has a high heat conductivity (approx. 220 W/mK) at economic conditions. The pipe spacing should be as small as possible; however, this results in the problem that many pipes are needed. Many pipes mean high costs since the pipes (made from copper as rule) are much more expensive than the thin aluminum fins. These material costs could be reduced in that the pipe diameter and the wall thickness are reduced, i.e. a heat exchanger is made with a number of small pipes instead of with a few larger pipes. This solution would be ideal thermodynamically: Very many pipes at small distances with small diameters. A substantial cost factor is, however, also the working time for the widening and soldering or brazing of the pipes. It would increase extremely with such a geometry.

A new class of heat exchangers, so-called mini-passage or also micro-passage heat exchangers, was therefore already developed some years ago which are manufactured using a completely different process and almost correspond to the ideal of a finned heat exchanger: many small pipes at small intervals.

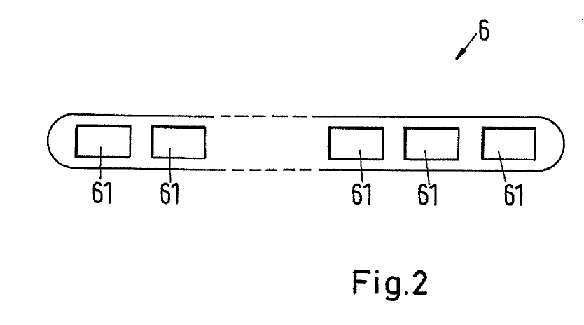

Instead of small pipes, however, extruded aluminum sections are used in the mini-passage heat exchanger which have very many small passages with a diameter of e.g. approximately 1 mm. Such an extruded section likewise known per se is shown schematically e.g. in FIG. 2. Such sections can e.g. be manufactured in suitable extrusion processes simply and in a variety of shapes from a plurality of materials. However, other manufacturing processes are also known for the manufacture of mini-passage heat exchangers such as the assembly of suitably shaped sectional metal sheets or other suitable processes.

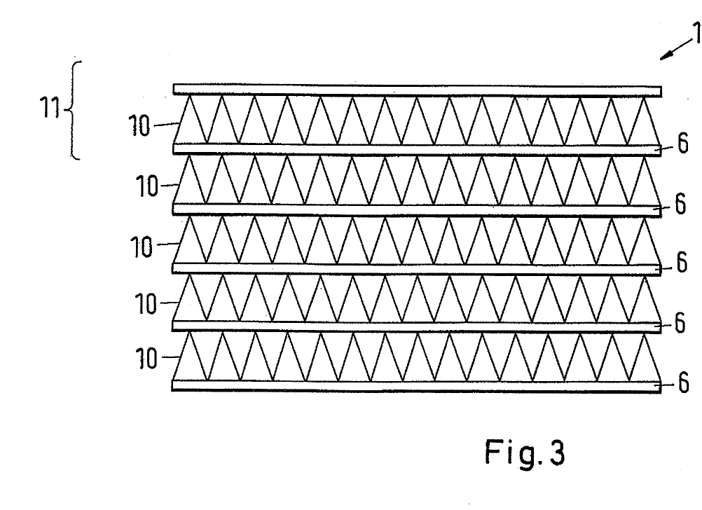

These sections cannot be expanded and they are also not pushed into stamped fin packets. Instead, for example, sheet metal strips, in particular aluminum strips, are placed between two sections disposed close to one another (common spacings, for example, <1 cm) so that a heat exchanger packet arises by alternating placing of sheet metal strips and sections next to one another. This packet is then soldered or brazed completely in a soldering or brazing furnace. FIG. 3 e.g. shows such a packet.

A heat exchanger having a very high fin efficiency and a very small filling volume (inner passage side) arises due to the narrow spacings and the small passage diameters. The further advantages of this technique are the avoidance of material pairings (corrosion), the low weight (no copper), the high pressure stability (approx. 100 bar) as well as the compact construction shape (typical depth of a heat exchanger e.g. 20 mm).

The disadvantages are the complicated manufacturing process which requires a soldering or brazing furnace, the limited dimensions which are preset by the soldering or brazing furnace, the restricted connection possibility (pass number), but above all the complex and/or expensive connection system (inlet tank and outlet tank).

Mini-passage heat exchangers became established in mobile use in the course of the 1990s. The low weight, the small block depth as well as the restricted dimensions required here are the ideal requirements for this. Automotive radiators as well as condensers and evaporators for automotive air-conditioning systems are today realized almost exclusively with mini-passage heat exchangers.

In the stationary area, larger heat exchangers are usually needed, on the one hand; on the other hand, the emphasis here is less on the weight and the compact design and more on the ideal price-performance ratio. Mini-passage heat exchangers were previously too limited in dimensions to be considered for this purpose. Many small modules would have had to be connected to one another in a complex and/or expensive manner. In addition, the use of aluminum is relatively high in the extruded sections so that a cost advantage was also practically not to be expected from the material use aspect.

Due to the high volumes in the automotive sector, the manufacturing processes for mini-passage heat exchangers has become standardized and has improved so that this technology can today be called mature. The soldering or brazing furnace size has also increased in the meantime so that heat exchangers can already be produced in the size of approximately 1×2 m. The initial difficulties with the connection system have been remedied. In the meantime, there are a plurality of patented processes on how the inlet tanks and outlet tanks can be soldered or brazed in.

However, above all the price of copper, which has increased greatly with respect to aluminum, has had the result that this technology is also becoming interesting for stationary use.

In addition to the simple systems in which substantially only one environmental medium, such as air, is available to the heat exchanger for the exchange of heat, so-called hybrid coolers or hybrid dry coolers are known such as are e.g. disclosed in WO 90/15299 or in EP 428 647 B1, in which the gaseous or liquid medium of the primary cooling circuit to be cooled flows through a finned heat exchanger and which outputs the heat to be dissipated via the cooling fins to the air flow partly as sensitive heat and partly as latent heat. One or more fans convey the air flow through the heat exchanger and advantageously have variable speeds. The dissipation of the latent heat takes place by a liquid medium, preferably water, which is matched from its specific values such as conductivity, hardness, carbonate content and is in each case added to the heat transfer surface at the air side as a drop-forming liquid film. The excess water drips into a collection bowl directly beneath the heat exchanger elements. Sprayed heat exchanger concepts are also known where water is sprayed onto the finned heat exchanger and evaporates completely and in this process the evaporation energy is used for the improvement of the heat transfer as in the wetting for energetic optimization. It is also possible to work without a water excess here, but a formation of deposits has to be prevented, for which purposes e.g. VE water is used.

It is understood that other cooling fluids such as oil can also be considered in addition to water in special cases.

The manner of operation in the wetting or spraying of the fins of the heat exchanger results in substantial energy and water savings in comparison with customary methods such as with open cooling towers. However, the restriction in the choice of material of the wetted or sprayed heat exchanger pipe in conjunction with the fin where corrosion may not occur in connection with an electrolyte is disadvantageous.

Hybrid heat transfer is thus understood as the substantial improvement of the heat transfer of fin heat transfer devices with pipes by direct wetting or spraying of water. It is above all necessary in this respect to regulate the air speed in the fin packet so that no taking along of water occurs at the fin surface. This is advantageously achieved by a speed regulation of the fans or by other suitable measures.

It is a disadvantage in this respect that the sprayed or wetting water acts as an electrolyte together with dissolved ions, which can result in numerous corrosion problems with the usually used material pairings of copper pipe and aluminum fins of the heat exchanger.

It is known in this respect e.g. to use so-called cataphoretic dip coating as a suitable surface protection for heat exchangers. Furthermore, both the material pairings such as copper pipe and copper fins and aluminum pipe and aluminum fins as well as stainless steel pipe and stainless steel fins are used to master the problems of contact corrosion. It is also known to zinc coat the heat exchangers completely. High demands are made on the quality of the circulation water or spray water in this respect with regard to the pH values, water hardness, chlorine content, conductivity, etc. to prevent deposits from forming which are too big, on the one hand, on condensation on the fin due to evaporation and from contents of chemically reactive materials forming, on the other hand, which can on their part result in corrosion together with the deposits.

A decisive disadvantage in this respect is that the effort and/or cost for the production and for the corrosion protection of the heat exchanger walls is very complex and/or expensive in a hybrid operation.

To achieve higher heat transfer capacities than are e.g. known with small heat exchangers from automotive engineering or domestic technology, attempts have previously been made to make use of the previously described hybrid technology with larger heat transfer systems.

Another possibility to reach larger heat transfer capacities basically involves trying to achieve greater exchange capacities by interconnection of a plurality of individual heat exchange components, e.g. by the connection of Al-MCHX modules.

In this respect, the problem results in practice, however, that thermal stresses can occur in the modules or connection points which frequently result in damage to or even to the destruction of the heat exchanger system so that sufficiently large heat quantities cannot be exchanged to date in practice in this manner.

These thermal stresses occur in refrigeration engineering and in dry cooler engineering as well as generally in heat exchange, e.g. in externally installed units in winter, in particular at very low outside temperatures, e.g. at up to or below −30° C., and/or also in amplified form in the operation of the heat exchangers with hot gas supply temperatures or coolant supply temperatures of up to 120° C.

The problem of the thermal stresses is thus in no way limited to large, stationary heat exchange systems, but rather occurs everywhere where large temperature differences and/or large amounts of heat have to be exchanged and/or compensated.

It is therefore the object of the invention to provide an improved heat exchange system which overcomes the problems known from the prior art and with which in particular high cooling rates can be achieved with minimum wear and at low costs, in particular with large stationary systems, but also with mobile systems. It is a further object of the invention to provide a method for the manufacture of such a heat exchange system.

The subjects of the invention satisfying these objects are characterized by the features of the independent claim of the respective category.

The respective dependent claims relate to particularly advantageous embodiments of the invention.

The invention thus relates to a heat exchange system with a heat exchanger for the exchange of heat between a fluid and an environmental atmosphere. The heat exchanger in this respect includes an inlet passage, an outlet passage and a heat transfer device with a plurality of micro-passages, with the inlet passage being in flow communication with an inlet segment of the heat transfer device and the outlet passage being in flow communication with an outlet segment of the heat transfer device such that the fluid for the exchange of heat with the environmental atmosphere can be supplied from the inlet passage via the inlet segment, through the plurality of micro-passages of the heat transfer device, and to the outlet passage via the outlet segment. In accordance with the invention, the heat exchange system includes a compensation means for the compensation of thermomechanical strains.

The invention relates, among other things, to a heat exchange system, in particular for refrigeration and air conditioning systems and relates specifically to soldered or brazed heat exchangers, in particular, but not only, to aluminum heat exchangers, for the hybrid or non-hybrid cooling of a refrigeration means, for example a liquid refrigeration means, or for the liquefying of refrigerants, in a particular embodiment with a water-wettable or sprayable heat transfer surface at the air side via which a cooling means can be conducted or completely evaporated in a circuit.

In accordance with the invention, a thermal expansion of the components resulting in this respect in the operating state is compensated by suitable connection techniques to increase operating safety and leak security.

The invention can be used particularly advantageously in cold conditions, e.g. far below room temperature, at −30° C., for example, or at even lower temperatures, inter alia in the operation of a heat exchange system as an evaporator or air cooler in the cold storage house or in spaces to be cooled and in defrosting by means of hot gas.

The present invention proves particularly advantageous on the connection of a plurality of cooling modules to increase the cooling capacity. The avoidance of thermomechanical strains takes place in accordance with the invention by compensators which allow the individual modules to be able to compensate strains, for example, with respect to the pipe connection point.

In specific embodiments of the present invention, aluminum corrugated pipes, in particular soldered or brazed to the modules, flexible hoses or other connection elements are proposed as compensation means which can compensate thermomechanical strains. Solderable or brazable aluminum alloys, e.g., but not necessarily, with a small magnesium portion, can be considered as materials, e.g. in the case of corrugated pipes or in the case of similar firm connection techniques. These flexible connections can also be realized by corresponding spacings between inlet tanks and connection points, optionally also in the form of U bends. With heat exchange systems made in V shape or in W shape, a central inlet tank located in the middle can e.g. be provided for temperature compensation.

The present invention can in this respect in particular also be used particularly advantageously when very large cooling capacities are required and where the connection of more than two, three or more than four modules therefore has to be provided.

In this respect, the invention relates, in addition to simple cooling systems, also to hybrid dry coolers or liquefiers, i.e. heat exchange systems in which a heat exchanger surfaces is additionally wetted for sprinkled with a cooling fluid, e.g. with water, oil or with another fluid for the heat exchange.

In a specific embodiment, the compensation means is a stretchable and/or a flexible connection means, in particular a corrugated pipe and/or a flexible hose, specifically a metal connection sheet and/or another suitable compensation means which can preferably be made of a metal or of a metal alloy, but especially also e.g. from a plastic, a composite material or another suitable material.

In an embodiment important for practice, at least two heat transfer devices are provided in a heat exchange system in accordance with the invention and/or the at least two heat transfer devices are connected via am inlet line of the inlet tank and/or via an outlet line of the inlet tank for the inflow or outflow respectively of a cooling fluid. The required heat exchange capacity can be matched very flexibly in accordance with the demand in the specific case by the interconnection of at least two heat transfer devices in a heat exchange system in accordance with the invention.

For the further improvement of the heat exchange capacity, the heat exchange system can include a heat exchange body so that a heat exchanger packet is formed from the heat exchange body and the heat transfer device. The heat exchange body can e.g. be a metal cooling plate known per se or a cooling rib or another suitable heat exchange body such as is known from the prior art.

In an embodiment important for practice, the heat exchange system includes a plurality of heat transfer devices and/or a plurality of heat exchangers and/or a plurality of heat exchange bodies and/or a plurality of heat exchange packets and is in particular made as a modular heat exchange system. It is particularly preferably made as a modularly extensible and/or modularly reducible heat exchange system which can be adapted easily and at a favorable cost very flexibly to changing demands, e.g. to changing demands on the heat exchange capacity, without the complete heat exchange system having to be replaced in a corresponding case.

The compensation means in accordance with the invention can in this respect be provided between different components of the heat exchange system. The compensation means can thus be provided between the heat transfer device and/or the inlet passage and/or the outlet passage.

And/or the compensation means can be provided between the heat transfer device and/or the inlet line of the inlet tank and/or the outlet line of the inlet tank and/or between the heat exchange body and the heat transfer device and/or between two heat exchange packets.

Preferably, but not necessarily, two heat transfer devices and/or two heat exchangers and/or two heat exchange packets are arranged at a presettable angle to one another, are in particular arranged in parallel and/or in V shape and/or in W shape to one another.

In this respect, a separate compensation means does not necessarily have to be provided as a compensation means for the compensation of thermomechanical strains. In specific cases, it is also possible that the inlet passage itself and/or the outlet passage and/or the inlet segment and/or the outlet segment and/or the inlet line of the inlet tank and/or the outlet line of the inlet tank and/or the heat exchanger packet are made as compensation means in that they are made e.g. as compensation means in the form of a corrugated pipe or of an elastic or stretchable hose or in another suitable form.

In particular when particularly high heat transfer capacities are required, a heat exchange system in accordance with the present invention can include a cooling device for the cooling of the heat transfer device; in particular a fan can be provided at the heat transfer device for the generation of a gas flow in a manner known per se.

In order possibly to cope with even larger heat transfer capacities, the heat exchange system can be made as a hybrid system and can include a sprinkling device for the sprinkling of the heat transfer device with a cooling fluid, in particular with a cooling water or cooling oil and/or a drop separator can be provided, e.g. in the form of a pan for the separation and collection of the cooling fluid.

The heat transfer device and/or the heat exchanger and/or the compensation means and/or the heat exchange body and/or the heat exchanger packet, specifically the whole heat exchange system, is made from a metal or from a metal alloy, in particular from a single metal or a single metal alloy, in particular from stainless steel, specifically from aluminum or from an aluminum alloy.

In this respect, a so-called sacrificial metal can be provided as corrosion protection which is e.g. corroded in a manner known to the skilled person in an electrochemical corrosion process in favor of, that is while maintaining, a different metallic component of the heat exchange system in accordance with the invention.

In this respect, it is also alternatively or additionally possible that the heat exchange system is at least partly provided with a protection layer, in particular with a corrosion protection layer, which can, for example, be a corrosion protection lacquer, a thermal spray coating, an electroplated layer or another suitable corrosion protection layer.

For very special applications in which the advantageous properties of a finned heat exchanger and of a micro-passage heat exchanger are required simultaneously, the heat exchange system can be made as a combination heat exchange with a finned heat exchanger with cooling fins r.

A heat exchange system of the present invention can in this respect be advantageously usable in a plurality of technical areas. The heat exchange system can thus, among a number of other application possibilities, be a radiator, in particular a radiator for a vehicle, specifically for a land vehicle, for an aircraft or for a water vehicle, or a cooler, a condenser or an evaporator for a mobile or stationary heating system, a refrigeration system or an air-conditioning system, in particular a cooler apparatus for a machine or a building.

The invention further relates to a method for the manufacture of a heat exchange system in accordance with the present invention, with a soldering or brazing process and/or a welding process preferably being used.

The heat exchange system is preferably manufactured in a soldering or brazing furnace, with the components of the heat exchange system specifically being mechanically connected and subsequently being soldered or brazed in a soldering or brazing step.

For protection against corrosive or other damaging environmental influences, the heat exchange system can be provided at least partly in a manner known per se with a protection layer, in particular with a corrosion protection layer and/or with a sacrificial metal, after the soldering or brazing.

The invention will be explained in more detail in the following with reference to the drawing. There are shown in a schematic representation:

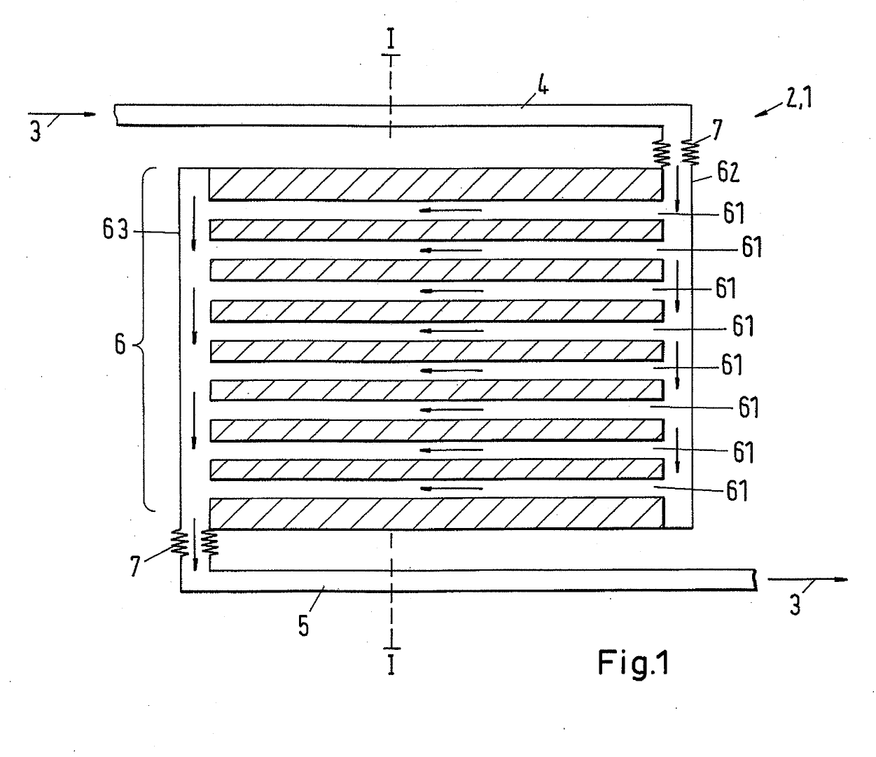

FIG. 1 a first embodiment of a heat exchange system in accordance with the invention;

FIG. 2 a heat transfer device with micro-passages in section along the line I-I in accordance with FIG. 1:

FIG. 3 a heat exchange system with heat exchange packets;

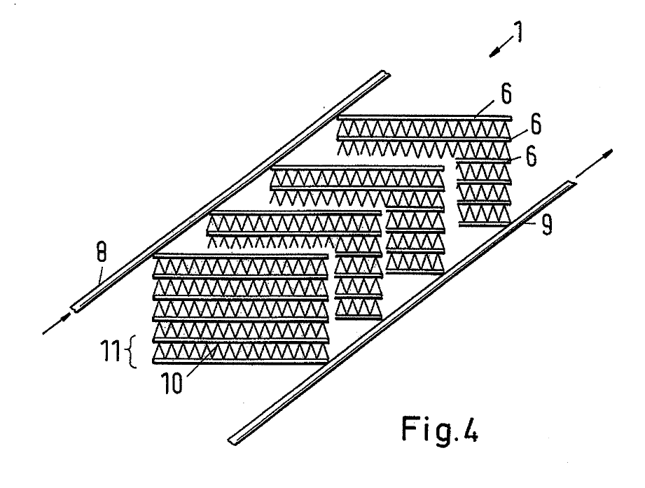

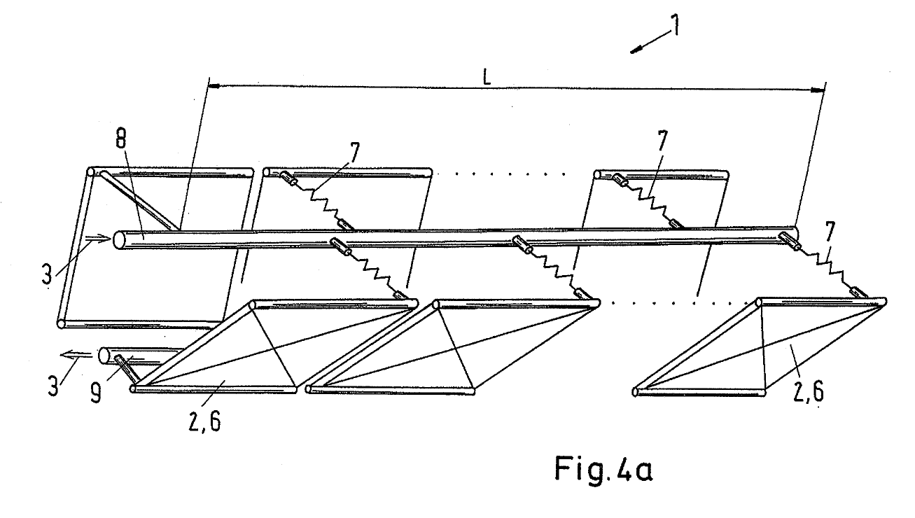

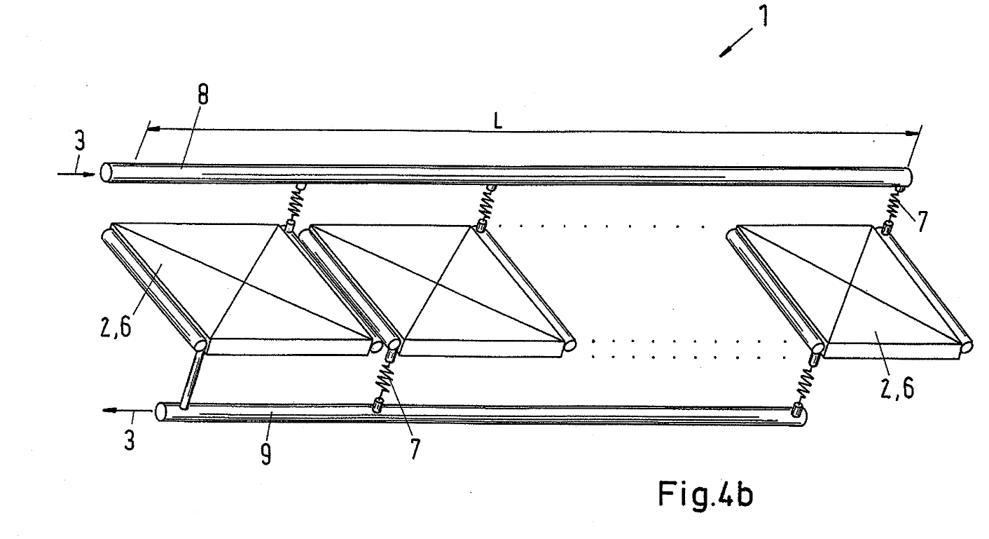

FIG. 4 a modular heat exchange system in a parallel arrangement;

FIG. 4a a further modular heat exchange system;

FIG. 4b a third modular heat exchange system;

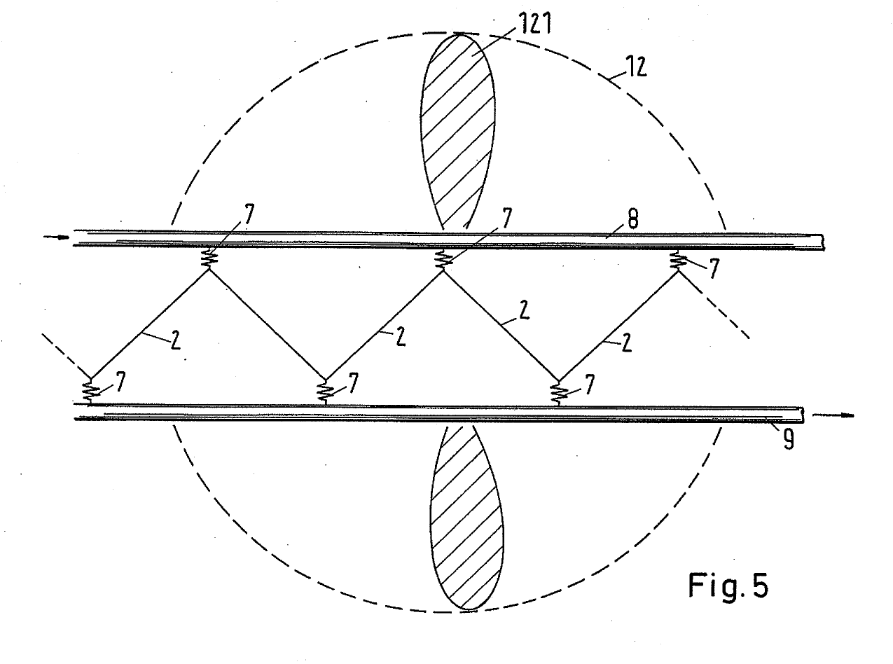

FIG. 5 a heat exchange system with heat exchangers arranged in V shape;

FIG. 6 a finned heat exchanger for the formation of a combination heat exchanger; and

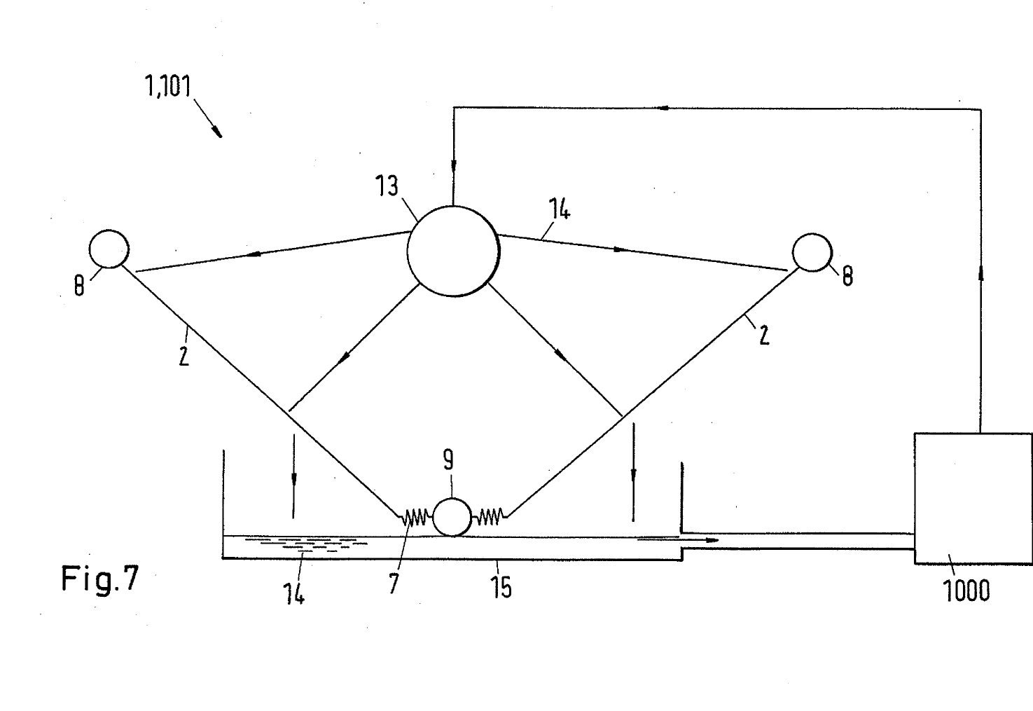

FIG. 7 a heat exchange system as a hybrid system with a sprinkling device.

FIG. 1 shows in a schematic representation a first simple embodiment of a heat exchange system in accordance with the invention which is provided as a whole with the reference numeral 1 in the following.

The heat exchange system 1 in accordance with the invention of FIG. 1 has as a major element a heat exchanger 2 for the exchange of heat between a fluid 3, e.g. a cooling liquid 3, and an environmental atmosphere, e.g. air. The heat exchanger 2 includes an inlet passage 4, an outlet passage 5 and a heat transfer device 6 having a plurality of micro-passages 61. The heat transfer device 6 is therefore e.g. a micro-passage system or mini-passage system 6 known per se. The inlet passage 4 is in flow communication with an inlet segment 62 of the heat transfer device 6 and the outlet passage 5 is in flow communication with an outlet segment 63 of the heat transfer device 6 such that the fluid 3 for the exchange of heat with the environmental atmosphere can be supplied from the inlet passage 4 via the inlet segment 62, through the plurality of micro-passages 61 of the heat transfer device 6, and finally via the outlet segment 63 to the outlet passage 5. It is essential to the invention in this respect that the heat exchange system 1 of FIG. 1 includes a compensation means 7 for the compensation of thermomechanical strains which in this present case is between the inlet passage 4 and the heat transfer device 6 or between the outlet passage 5 and the heat transfer device 6 so that thermomechanical strains occurring between the inlet passage 4 and/or the heat transfer device 6 and/or the outlet passage 5 can be compensated.

In FIG. 2, a heat transfer device 6 having micro-passages 61 is shown schematically in section along the line I-I in accordance with FIG. 1. Instead of small pipes, as already mentioned, extruded aluminum sections were e.g. used in mini-passage heat transfer devices 6 and have very many small passages 61 with a diameter of e.g. approximately 1 mm. The heat transfer device 6 of FIG. 2 can e.g. be manufactured simply and in a variety of shapes from a plurality of materials in a suitable extrusion process. The heat exchanger 2 in accordance with FIG. 2 can, however, also be manufactured in another embodiment variant not explicitly shown in FIG. 2, but also by other manufacturing processes such as e.g. by the assembly of suitably shaped sheet metal sections or by other suitable processes.

To increase and improve the heat exchange capacity, a heat exchange system 1 in accordance with the present invention can, as shown by way of example in FIG. 1, also be formed as a heat exchange packet 11 by a plurality of heat exchange bodies 10 which can form a heat exchange system in accordance with the invention overall. In the present example, the heat exchange bodies 10 are metal cooling sheets 10 which are arranged in a manner known per se in V shape or W shape between two heat transfer devices 6 which are shown e.g. schematically in FIGS. 1 and 2.

The specific embodiments of FIG. 4, FIG. 4a and FIG. 4b can be used particularly advantageously in practice above all, but not only, when changing heat transfer capacities have to be anticipated. For example when a heat exchange system 1 in accordance with the invention is used as a cooling system for the cooling of a large building complex or of a machine park whose size has to be redimensioned in the course of time, that is e.g. has to be reduced or increased in size, so that a smaller or larger heat transfer capacity becomes necessary. In this case, a modular heat exchange system 1 in accordance with FIG. 4, FIG. 4a or FIG. 4b is suitable in which a plurality of heat transfer devices 6 are provided, in a parallel arrangement e.g. in FIG. 4, between an inlet line 8 of the inlet tank and an outlet line 9 of the inlet tank. In this respect, other types of arrangement of the heat transfer devices 6 or of the heat exchangers 2 are naturally also possible between the inlet line 8 of the inlet tank and the outlet line 9 of the inlet tank, as will be demonstrated on two specific examples with reference to FIG. 4a and FIG. 4b. The heat exchangers 2 or the heat transfer devices 6 can thus, for example, also be arranged in a V-shaped arrangement or partially in a V-shaped arrangement in accordance with FIG. 4a, or also in a planar parallel arrangement in accordance with FIG. 4b or in any other suitable arrangement with respect to one another or with respect to the inlet line 8 of the inlet tank and/or the outlet line 9 of the inlet tank.

A heat exchange system 1 in accordance with the invention, as is shown inter alia schematically in FIG. 4, FIG. 4a and FIG. 4b, can in this respect have a length L of up to 6 m, specifically between 6 m and 12 m or even greater dimensions. It is understood that a heat exchange system in accordance with the invention can also be substantially smaller than 6 m, e.g. only 1 m, or even have smaller dimensions.

In this respect, a heat exchange system of the present invention can also be exposed without problem to very large temperature differences or temperature fluctuations up to 120° C. and more without any damage to or any impairment of the function having to be feared. Thanks to the compensation means 7 in accordance with the invention, which can all be flowed through by the fluid 3 or of which only some can be flowed through by the fluid, the heat exchange system of the present invention also copes with large length changes up to well into the percentage region with respect to a length L of the heat exchange system 1. It is understood in this respect that, depending on the type of the embodiment, any linear extent L can be meant by the length L of the heat exchange system 1.

In trials, length changes can be compensated, e.g. on the use of aluminum, of up to 0.3% or, in a heat exchange system 1 made of copper, length changes of up to 0.2%. In a specific case, in a heat exchange system 1 of aluminum with a length of 12,000 mm, a length change of up to 34 mm was able to be compensated easily. In a corresponding heat exchange system 1 of copper, length changes of up to 25 mm were able to be compensated, with corresponding temperature differences of up to 120° C. having been set.

A heat transfer device 6 or a heat exchanger 2 can be removed or added simply in a heat exchange system 1 in accordance with FIG. 4, FIG. 4a or FIG. 4b so that the heat exchange capacity of the heat exchange system 1 can be adapted extremely flexibly to changing demands.

FIG. 5 shows a heat exchange system 1 having heat exchangers 2 arranged in V shape, as is shown in detail e.g. in FIG. 1, with a fan 12, 121 additionally being provided to generate a gas flow to improve the cooling capacity.

For illustration, FIG. 6 shows a finned heat exchanger 16 known per se with cooling fins 161 such as can be used in very specific embodiments of the present invention, for example for the formation of a combination heat exchanger. This means that a heat exchange system 1 of the present invention can simultaneously include, in addition to a heat transfer device 6 with a plurality of micro-passages 61, a heat exchanger 16 with cooling fins 161 for very special applications.

To cope with possibly even larger heat transfer capacities, the heat exchange system 1 in accordance with FIG. 7 can be made as a hybrid system 1, 101. In this case, a sprinkling device 13 is preferably provided for the sprinkling of the heat transfer device 6 with an external cooling fluid 14, in particular with cooling water 14 or cooling oil 14. The specific embodiment of FIG. 7 additionally includes a drop separator 15 in the form of a pan 15 for the separation and collection of the external cooling fluid 14 so that the external cooling fluid 14 can be recirculated in an external cooling system 1000, which serves for the cooling of the external cooling fluid 14, and can, for the further cooling of the heat exchanger 2, be supplied to this again via the sprinkling device 13.

It is understood that the embodiments described within the framework of this application are only to be understood as examples. This means that the invention is not solely restricted to the specific embodiments described. All suitable combinations of the presented specific embodiments are in particular likewise covered by the invention.

It is possible for the first time by the present invention also to achieve larger heat transfer capacities in that larger exchange capacities can be achieved by interconnection of a plurality of individual heat exchange components, e.g. by the connection of Al-MCHC modules, without it having to be feared that the heat exchange system suffers damage from thermomechanical strains.

This means that the problem known from the prior art of thermal stresses in the modules or connection points which frequently result in damage to or in even the destruction of the heat exchanger system so that sufficiently large heat quantities could not be exchanged to date in this manner in practice, is completely eliminated by the present invention.

Thermal stresses such as occur in refrigeration engineering and dry air engineering, as well as generally in heat transfer, e.g. in externally installed units in winter, in particular at very low outside temperatures, e.g. at up to or below −30° C., and/or also can be observed in amplified form in the operation of the heat exchangers with hot gas supply temperatures or coolant supply temperatures of up to 120° C., now no longer represent any problem due to the use of a heat exchange system in accordance with the invention.

But not only the problems of thermal stresses in large, stationary heat exchange systems are eliminated by the present invention, but the heat exchange system of the present invention can also be used very advantageously in all other, also small, heat exchange systems, e.g. in systems for domestic appliances or vehicles, above all where large temperature differences and/or large quantities of heat have to be exchanged or compensated.

1. A heat exchange system with a heat exchanger (2) for the exchange of heat between a fluid (3) and an environmental atmosphere, wherein the heat exchanger (2) includes an inlet passage (4), an outlet passage (5) and a heat transfer device (6) having a plurality of micro-passages, and the inlet passage (4) is in flow communication with an inlet segment (62) of the heat transfer device (6) and the outlet passage (5) is in flow communication with an outlet segment (63) of the heat transfer device (6) such that the fluid (3) for the exchange of heat with the environmental atmosphere can be supplied from the inlet passage (4) via the inlet segment (62), through the plurality of micro-passages (61) of the heat transfer device (6), and via the outlet segment (63) to the outlet passage (5), characterized in that the heat exchange system (1) includes a compensation means (7) for the compensation of thermomechanical stresses.

2. A heat exchange system in accordance with claim 1, wherein the compensation means (7) is a stretchable and/or a flexible connection means (7), in particular a corrugated pipe (7) and/or a flexible hose (7), specifically a metal connection sheet (7) and/or another suitable compensation means (7).

3. A heat exchange system in accordance with claim 1, wherein at least two heat transfer devices (6) are provided and/or the at least two heat transfer devices (6) are connected via an inlet line (8) of an inlet tank and/or via an outlet line (9) of an inlet tank, and/or wherein the heat exchange system (1) includes a heat exchange body (10) and a heat exchange packet (11) is formed from the heat exchange body (10) and the heat transfer device (6), and/or wherein the heat exchange system (1) includes a plurality of heat transfer devices (6) and/or heat exchangers (2) and/or heat exchange bodies (10) and/or heat exchange packets (11), and is in particular made as a modular heat exchange system (1), is preferably made as a modularly expandable and/or modularly reducible heat exchange system (1).

4. A heat exchange system in accordance with claim 1, wherein the compensation means (7) is provided between the heat transfer device (6) and/or the inlet passage (4) and/or the outlet passage (5), and/or wherein the compensation means (7) is provided between the heat transfer device (6) and/or the inlet line (8) of the inlet tank and/or the outlet line (9) of the inlet tank, and/or wherein the compensation means (7) is provided between the heat exchange body (10) and the heat transfer device (6), and/or wherein the compensation means (7) is provided between two heat exchanger packets (11), and/or wherein two heat transfer devices (6) and/or two heat exchangers (2) and/or two heat exchanger packets (11) are arranged at a presettable angle to one another, are in particular arranged in parallel and/or in V-shape to one another.

5. A heat exchange system in accordance with claim 1, wherein the inlet passage (4) and/or the outlet passage (5) and/or the inlet segment (61) and/or the outlet segment (62) and/or the inlet line (8) of the inlet tank and/or the outlet line (9) of the inlet tank and/or the heat exchanger packet (11) are made as compensation means (7).

6. A heat exchange system in accordance with claim 1, wherein the heat exchange system (1) includes a cooling device (12) for the cooling of the heat transfer device (6), in particular a fan (12, 121) is provided for the generation of a gas flow, and/or wherein the heat exchange system (1) is made as a hybrid system (1, 101) and includes a sprinkling device (13) for the sprinkling of the heat transfer device (6) with a cooling fluid (14), in particular with cooling water (14), and/or wherein a drop separator (15) is provided for the separation of the cooling fluid (14).

7. A heat exchange system in accordance with claim 1, wherein the heat transfer device (6) and/or the heat exchanger (2) and/or the compensation means (7) and/or the heat exchange body (10) and/or the heat exchange packet (11), specifically the whole heat exchange system (1), is made from a metal or from a metal alloy, is in particular made from a single metal or from a single metal alloy, in particular from stainless steel, specifically from aluminum or an aluminum alloy, and/or wherein the heat transfer device (6) and/or the heat exchanger (2) and/or the compensation means (7) and/or the heat exchange body (10) and/or the heat exchanger packet (11), specifically the whole heat exchange system (1), is made from a metal or a metal alloy, wherein a sacrificial metal is provided as corrosion protection and/or wherein the heat exchange system is provided at least in part with a protection coating, in particular with a corrosion protection coating.

8. A heat exchange system in accordance with claim 1, wherein the heat exchange system forms a combination heat exchanger with a finned heat exchanger (16)8 with cooling fins (161).

9. A heat exchange system in accordance with claim 1, wherein the heat exchange system (1) is a radiator (1), in particular a radiator (1) for a vehicle, specifically for a land vehicle, for an aircraft or for a water vehicle, or a cooler (1), a capacitor (1) or an evaporator (1) for a mobile or stationary heating system, a cooling system or an air-conditioning system, in particular a cooling apparatus (1) for a machine, for a data processing system or for a building.

10. A method for the manufacture of a heat exchange system (1) in accordance with claim 1, wherein a soldering or brazing method and/or a welding method is used and/or wherein the heat exchange system (1) is manufactured in a soldering or brazing furnace and/or wherein the components of the heat exchange system (1) are mechanically connected and are subsequently soldered or brazed in a soldering or brazing step and/or wherein the heat exchange system (1) is provided after the soldering or brazing at least partly with a protection layer, in particular with a corrosion protection layer and/or with a sacrificial metal.
